(19) United States
(12) Patent Application Publication
(10) Pub. No.: US 2026/0090338 A1
(43) Pub. Date: Mar. 26, 2026

(54) MANUFACTURING METHOD OF SEMICONDUCTOR DEVICE AND SEMICONDUCTOR DEVICE

(71) Applicant: Renesas Electronics Corporation, Tokyo (JP)

(72) Inventor: Hideyuki TAJIMA, Tokyo (JP)

(21) Appl. No.: 19/267,749

(22) Filed: Jul. 14, 2025

(30) Foreign Application Priority Data
Sep. 24, 2024 (JP) 2024-165483

(51) Int. Cl. H01L 21/66; H01L 21/78; H03K 17/082; H10D 80/20

(52) U.S. Cl. CPC H10P 74/238; H03K 17/0822; H10D 80/213; H10D 80/251; H10P 54/00; H03K 2217/0027

(57) ABSTRACT

A manufacturing method of a semiconductor device capable of improving the accuracy of overcurrent detection is provided. The manufacturing method of a semiconductor device includes a semiconductor wafer testing process includes a first testing process to determine the resistance variation rate of the replica resistor due to manufacturing variations when manufacturing the semiconductor wafer, and a setting process to determine the variation value of the reference current based on the resistance variation rate determined in the first testing process and set the current value of the current circuit to reduce the variation value.

### CROSS-REFERENCE TO RELATED APPLICATIONS

The disclosure of Japanese Patent Application No. 2024-165483 filed on Sep. 24, 2024, including the specification, drawings and abstract is incorporated herein by reference in its entirety.

### BACKGROUND

The present invention relates to a method for manufacturing a semiconductor device and a semiconductor device, specifically to a method for manufacturing a semiconductor device equipped with an overcurrent detection circuit that detects overcurrent flowing through a power device, and to a semiconductor device equipped with such an overcurrent detection circuit.

There are disclosed techniques listed below.

Japanese Unexamined Patent Application Publication No. 2007-201116

For example, Patent Document 1 discloses an overcurrent detection circuit that detects overcurrent flowing through a power device.

For example, paragraphs and of Patent Document 1 show that the overcurrent detection circuit can be configured using a sense resistor and a comparator. In this overcurrent detection circuit, the sense voltage generated by the current flowing through the sense resistor is compared with a reference voltage by the comparator. When overcurrent flows through the sense resistor, the output of the comparator is inverted, thereby detecting the overcurrent.

### SUMMARY

The inventors have considered that improving the accuracy of overcurrent detection will continue to be important. However, it has been found that there is a problem that the resistance value of the sense resistor varies due to manufacturing variations, making it difficult to improve the accuracy of overcurrent detection.

A summary of representative embodiments disclosed in this application is as follows.

Namely, a manufacturing method of a semiconductor device according to one embodiment includes a semiconductor wafer manufacturing process in which a plurality of semiconductor chips, each having a power device and an overcurrent detection circuit that detects a current flowing through the power device, are arranged, a semiconductor wafer testing process for testing the semiconductor wafer, and a semiconductor device assembly process having dicing the plurality of semiconductor chips from the semiconductor wafer and assembling a semiconductor device equipped with the diced semiconductor chip. The overcurrent detection circuit includes a sense device through which a sense current proportional to the current flowing through the power device flows, a sense resistor connected between the sense device and a predetermined node, a reference resistor connected between the predetermined node and a current circuit, and a comparison circuit that compares the sense voltage generated in the sense resistor by the sense current with the reference voltage generated in the reference resistor by the reference current from the current circuit to form an overcurrent detection signal. The semiconductor chip includes a replica resistor arranged adjacent to the sense resistor. The semiconductor wafer testing process includes a first testing process to determine the resistance variation rate of the replica resistor due to manufacturing variations when manufacturing the semiconductor wafer, and a setting process to determine the variation value of the reference current based on the resistance variation rate determined in the first testing process and set the current value of the current circuit to reduce the variation value.

Other objects and novel features will become apparent from the description of this specification and the accompanying drawings.

According to one embodiment, it is possible to provide a method for manufacturing a semiconductor device that can improve the accuracy of overcurrent detection.

### BRIEF DESCRIPTION OF THE DRAWINGS

FIG. 1 is a circuit diagram showing the configuration of a semiconductor device according to the first embodiment.

FIG. 2 is a flowchart showing the manufacturing method of the semiconductor device according to the first embodiment.

FIG. 3A is a diagram for explaining the semiconductor wafer according to the first embodiment.

FIG. 3B is a diagram for explaining the semiconductor wafer testing process according to the first embodiment.

FIG. 3C is a diagram for explaining the semiconductor chip according to the first embodiment.

FIG. 4 is a flowchart showing the semiconductor wafer testing process according to the first embodiment in detail.

FIG. 5 is a diagram for explaining the first testing process according to the first embodiment.

FIG. 6 is a diagram for explaining the second testing process according to the first embodiment.

FIG. 7 is a diagram for explaining the second testing process according to the first embodiment.

FIG. 8 is a diagram for explaining the third testing process according to the first embodiment.

FIG. 9 is a circuit diagram showing the configuration of a variable current circuit according to the first embodiment.

FIG. 10A is a block diagram showing a main part of a semiconductor device according to the second embodiment.

FIG. 10B is a circuit diagram showing a configuration of the test current circuit.

FIG. 11 is a circuit diagram showing the configuration of the overcurrent detection circuit considered by the inventors.

FIG. 12 is a diagram for explaining the first embodiment.

### DETAILED DESCRIPTION

The various embodiments of the present invention will be described below with reference to the drawings. It should be noted that the disclosure is merely an example, and those skilled in the art can easily conceive of appropriate modifications that maintain the spirit of the invention, which are naturally included within the scope of the present invention.

Furthermore, in this specification and the drawings, elements similar to those previously described with respect to the previously mentioned figures are denoted by the same reference numerals, and detailed descriptions may be omitted as appropriate.

### Comparative Example

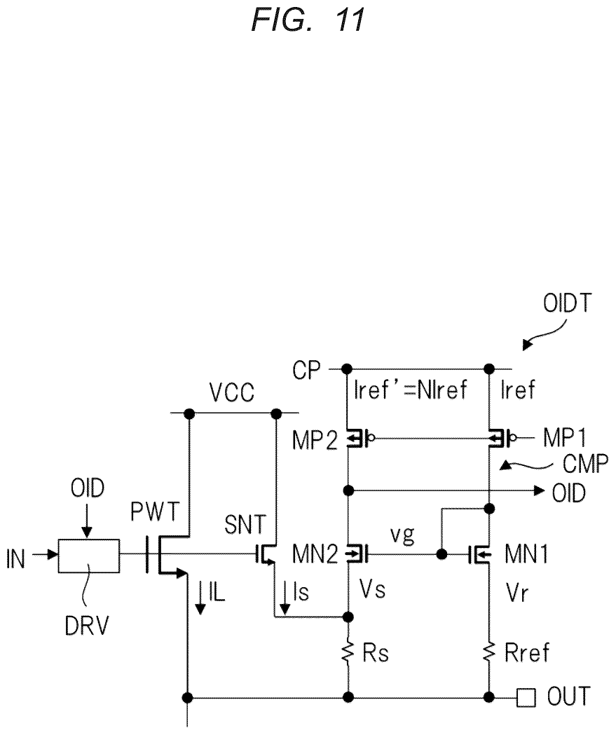

First, the inventors will explain the issues in more detail using the overcurrent detection circuit they considered. FIG. 11 is a circuit diagram showing the configuration of the overcurrent detection circuit considered by the inventors.

In FIG. 11, PWT represents a power device (power transistor), specifically an N-channel type field-effect transistor (hereinafter also referred to as an N-type transistor). The source-drain path of the N-type transistor PWT is connected between the power supply voltage VCC and the output terminal OUT. The gate of the N-type transistor PWT is connected to the control driver DRV. The control driver DRV supplies a drive signal to the gate of the N-type transistor PWT according to the input signal IN when no overcurrent is flowing through the N-type transistor PWT. When the N-type transistor PWT becomes conductive due to the drive signal, current is supplied from the power supply voltage VCC to the output terminal OUT, thereby driving the load connected to the output terminal OUT (not shown).

In FIG. 11, OIDT represents the overcurrent detection circuit. The overcurrent detection circuit OIDT includes an N-type transistor SNT as a sense device (sense transistor), a sense resistor Rs, a reference resistor Rref, N-type transistors MN1, MN2, and P-channel type field-effect transistors (hereinafter also referred to as P-type transistors) MP1, MP2.

The gate of the N-type transistor SNT, which is the sense device, is connected to the gate of the N-type transistor PWT, its drain is connected to the power supply voltage VCC, and its source is connected to the output terminal OUT via the sense resistor Rs. In this comparative example, the size of the N-type transistor SNT, which is the sense device, is set to 1/K (hereinafter also referred to as the size ratio K) relative to the size of the N-type transistor PWT, which is the power device. Thus, when both the N-type transistors PWT and SNT are made conductive by the control driver DRV, the value of the current (sense current) Is flowing through the source-drain path of the N-type transistor SNT becomes 1/K times the value of the current IL flowing through the source-drain path of the N-type transistor PWT.

The source-drain path of the P-type transistor MP1, the source-drain path of the N-type transistor MN1, and the reference resistor Rref are connected in series between the power supply voltage (for example, the output voltage of a boost circuit) CP and the output terminal OUT in this order. Similarly, the source-drain path of the P-type transistor MP2, the source-drain path of the N-type transistor MN2, and the sense resistor Rs are also connected in series between the power supply voltage CP and the output terminal OUT in this order.

The gates of the P-type transistors MP1 and MP2 are connected to each other and to a predetermined bias voltage (not shown). Additionally, the size of the P-type transistor MP2 is set to N times that of the P-type transistor MP1. As a result, the current Ib′ flowing through the source-drain path of the P-type transistor MP2 is set to N times (=NIb) the current Ib flowing through the source-drain path of the P-type transistor MP1.

The gate of the N-type transistor MN1 is connected to its drain and also to the gate of the N-type transistor MN2. Furthermore, an overcurrent detection signal OID is output from the connection node connecting the N-type transistor MN2 and the P-type transistor MP2.

In the overcurrent detection circuit OIDT shown in FIG. 11, the reference current Iref is supplied from the power supply voltage CP to the reference resistor Rref via the P-type transistor MP1 and the N-type transistor MN1. Additionally, the reference current Iref′ is supplied to the sense resistor Rs from the power supply voltage CP via the P-type transistor MP2 and the N-type transistor MN2, and the sense current Is is further supplied from the N-type transistor SNT. Consequently, the reference voltage Vr is generated by the reference current Iref in the reference resistor Rref, and the sense voltage Vs is generated by the reference current Iref′ and the sense current Is in the sense resistor Rs.

The N-type transistors MN1 and MN2 essentially form a comparison circuit CMP, and an overcurrent detection signal OID corresponding to the sense current Is is generated. This overcurrent detection signal OID is supplied to the control driver DRV. When the control driver DRV is notified of overcurrent detection by the overcurrent detection signal OID, it outputs a drive signal that turns the N-type transistors PWT and SNT into a non-conductive state, regardless of the input signal IN. This prevents the power device, the N-type transistor PWT, from being destroyed.

In the comparative example, the sense current Is flows, causing the sense voltage Vs to change. Due to this change in the sense voltage Vs, the voltage at the source of the N-type transistor SNT, which is the sense device, rises compared to the voltage at the source of the N-type transistor PWT, which is the power device. As a result, the ratio between the current IL flowing through the N-type transistor PWT and the sense current Is flowing through the N-type transistor SNT does not match the size ratio K. In other words, an error occurs in the size ratio K, leading to an error in the overcurrent detection circuit OIDT.

Furthermore, due to manufacturing variations, if the resistance value of the sense resistor Rs varies, the change in the sense voltage Vs also varies, causing the size ratio K to vary, resulting in further errors in the overcurrent detection circuit OIDT. The inventors have confirmed that the size ratio K depends on the sense resistor Rs and the sense voltage Vs, and there is a proportional relationship between the variation in the sense resistor Rs and the variation in the size ratio K. For example, if the value of the sense resistor Rs increases due to manufacturing variations, the sense voltage Vs and the size ratio K also increase. As an example, if the resistance value of the sense resistor Rs varies by ±30% due to manufacturing variations, when the sense voltage Vs is about 0.1V, the size ratio K varies by about ±15%, making it difficult to improve the accuracy of overcurrent detection.

As a method to obtain a semiconductor device with high accuracy in overcurrent detection, it is conceivable to select semiconductor devices with high accuracy in overcurrent detection during the manufacturing process of the semiconductor device. For example, in the final test process conducted during the manufacturing process, it is conceivable to select and ship those with high accuracy in overcurrent detection. However, in this case, the yield decreases, and since it is not possible to pre-select and discard those with low accuracy before reaching the final test process, the materials and labor invested up to the final test process are wasted, further reducing the overall yield.

### (First Embodiment) <Configuration of the Semiconductor Device>

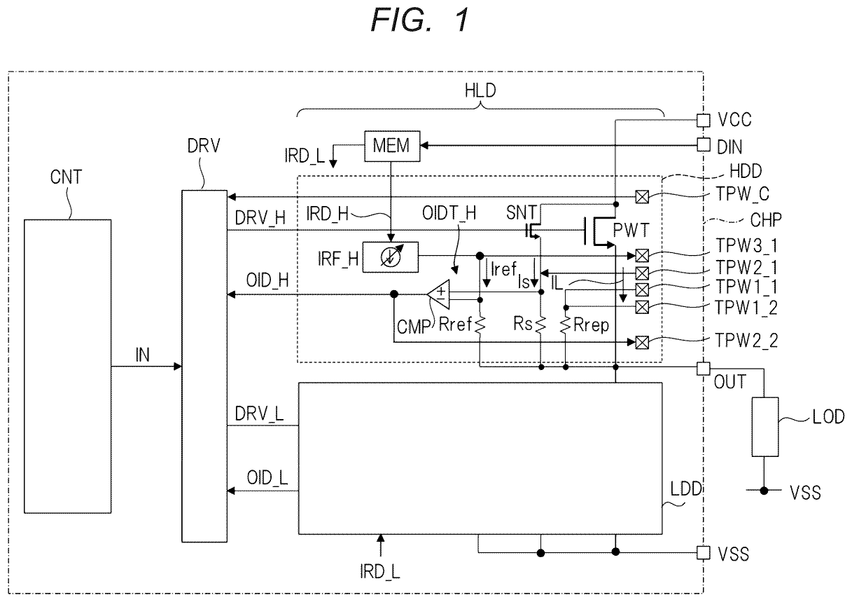

FIG. 1 is a circuit diagram showing the configuration of a semiconductor device according to the first embodiment. In FIG. 1, CHP indicated by a dashed line represents the semiconductor device. The semiconductor device CHP according to the first embodiment, which will be described later, includes a semiconductor chip cut from a semiconductor wafer, a package that seals the semiconductor chip, and external terminals protruding from the package.

The semiconductor device CHP is equipped with numerous external terminals, but in FIG. 1, only the external terminals necessary for explanation are depicted on the dashed line. In FIG. 1, VCC indicates the external terminal for power supply, VSS indicates the external terminal for ground voltage, DIN indicates the input external terminal for data input, and OUT indicates the output external terminal. These external terminals are electrically connected to circuit elements and circuit blocks formed on the semiconductor chip within the package.

The semiconductor device CHP includes a drive circuit HLD that drives a load LOD connected between the output external terminal OUT and the ground voltage external terminal VSS, and a control driver DRV that controls the drive circuit HLD according to the input signal IN from the control circuit CNT, and a memory circuit MEM. The drive circuit HLD includes a high-side drive circuit HDD and a low-side drive circuit LDD. Since the low-side drive circuit LDD is similar to the high-side drive circuit HDD, the high-side drive circuit HDD will be described as a representative example here.

The high-side drive circuit HDD includes an N-type transistor PWT, which is a power device (power transistor) with a source-drain path connected between the power supply external terminal VCC and the output external terminal OUT, a high-side overcurrent detection circuit OIDT_H, and a replica resistor Rrep.

The high-side overcurrent detection circuit OIDT_H includes an N-type transistor SNT, which is a sense device (sense transistor) on the high-side, a high-side variable current circuit IRF_H, a high-side reference resistor Rref, a high-side sense resistor Rs, and a high-side comparison circuit CMP. The gate of the N-type transistor SNT is connected to the gate of the N-type transistor PWT, its drain is connected to the external power supply terminal VCC, and its source is connected to the external output terminal OUT via the sense resistor Rs. The reference resistor Rref is connected between the variable current circuit IRF_H and the external output terminal OUT. The negative input terminal (denoted by − in FIG. 1) of the comparison circuit CMP is connected to the connection node that connects the reference resistor Rref and the variable current circuit IRF_H, and the positive input terminal (denoted by +) is connected to the connection node that connects the sense resistor Rs and the source of the N-type transistor SNT.

The variable current circuit IRF_H is supplied with high-side current data (also referred to as H current data) IRD_H from the memory circuit MEM, generates a reference current Iref of the current value specified by this H current data IRD_H, and outputs it. The memory circuit MEM is supplied with data from the external input terminal DIN and generates H current data IRD_H according to the supplied data. In the first embodiment, the memory circuit MEM and the variable current circuit IRF_H are collectively referred to as the current circuit. Also, the output external terminal OUT is also referred to as a predetermined node.

The comparison circuit CMP compares the reference voltage generated in the reference resistor Rref by the reference current Iref with the sense voltage generated in the sense resistor Rs by the sense current Is, and for example, when the sense voltage generated in the sense resistor Rs exceeds the reference voltage generated in the reference resistor Rref, it outputs a high-level overcurrent detection signal OID_H to the control driver DRV. Although not particularly limited, in the first embodiment, when the overcurrent detection signal OID_H is at a low level, it indicates that no overcurrent is detected in the high-side overcurrent detection circuit OIDT_H (no overcurrent is flowing through the N-type transistor PWT), and when the overcurrent detection signal OID_H is at a high level, it indicates that overcurrent is detected in the high-side overcurrent detection circuit OIDT_H (overcurrent is flowing through the N-type transistor PWT).

When the overcurrent detection signal OID_H is at a low level, that is, when no overcurrent is detected in the high-side overcurrent detection circuit OIDT_H, the control driver DRV supplies a drive signal DRV_H to the gates of the N-type transistors PWT and SNT to bring them into a conductive state according to the input signal IN from the control circuit CNT. As a result, the N-type transistor PWT supplies a current IL according to the drive signal DRV_H to the output terminal OUT, and the N-type transistor SNT outputs a sense current Is proportional to the current IL to the sense resistor Rs. In contrast, when the overcurrent detection signal OID_H is at a high level, that is, when overcurrent is detected in the high-side overcurrent detection circuit OIDT_H, the control driver DRV supplies a drive signal DRV_H to the gates of the N-type transistors PWT and SNT to bring them into a non-conductive state, regardless of the input signal IN from the control circuit CNT. This makes it possible to prevent the N-type transistor PWT from being destroyed.

The sense resistor Rs and the reference resistor Rref according to the first embodiment are configured by connecting a plurality of unit resistors in series, parallel, or series-parallel. In other words, the sense resistor Rs and the reference resistor Rref are configured by combining a plurality of resistors (unit resistors) with the same resistance value.

In FIG. 1, the symbols TPW1_1, TPW1_2, TPW2_1, TPW2_2, TPW3_1, and TPW_C, represented by squares filled with x, indicate pads within the semiconductor device CHP. In the first embodiment, these pads are not connected to the external terminals (indicated by squares in FIG. 1) of the semiconductor device CHP. That is, the pads do not protrude outside the semiconductor device CHP. As will be described later, the pads TPW1_1, TPW1_2, TPW2_1, TPW2_2, TPW3_1, and TPW_C are connected to a tester device during the semiconductor wafer test process.

In the first embodiment, the replica resistor Rrep is configured by the same unit resistor that constitutes the sense resistor Rs. Furthermore, the unit resistor that constitutes the replica resistor Rrep is arranged adjacent to the plurality of unit resistors that constitute the sense resistor Rs on the semiconductor chip. This results in the occurrence of resistance value variations similar to those occurring in the sense resistor Rs due to manufacturing variations (manufacturing variability) also occurring in the replica resistor Rrep.

In FIG. 1, DRV_L indicates the drive signal (corresponding to DRV_H) supplied from the control driver DRV to the low-side drive circuit LDD, OID_L indicates the low-side overcurrent detection signal (corresponding to OID_H), and IRD_L indicates the L current data (corresponding to IRD_H) supplied from the memory circuit MEM to the variable current circuit within the low-side drive circuit LDD (corresponding to IRF_H).

In FIG. 1, an example is shown where the high-side drive circuit HDD and the low-side drive circuit LDD are connected to a common output external terminal OUT, but this is not limited to this configuration. For example, the output external terminal OUT may be divided into two, one for the high-side drive circuit HDD and one for the low-side drive circuit LDD, and the load LOD may be connected in series between the two output external terminals. Additionally, the overcurrent detection circuit may be provided in only one of the high-side drive circuit HDD or the low-side drive circuit LDD, rather than in both.

### <Manufacturing Method of the Semiconductor Device, Semiconductor Wafer, and Test Device>

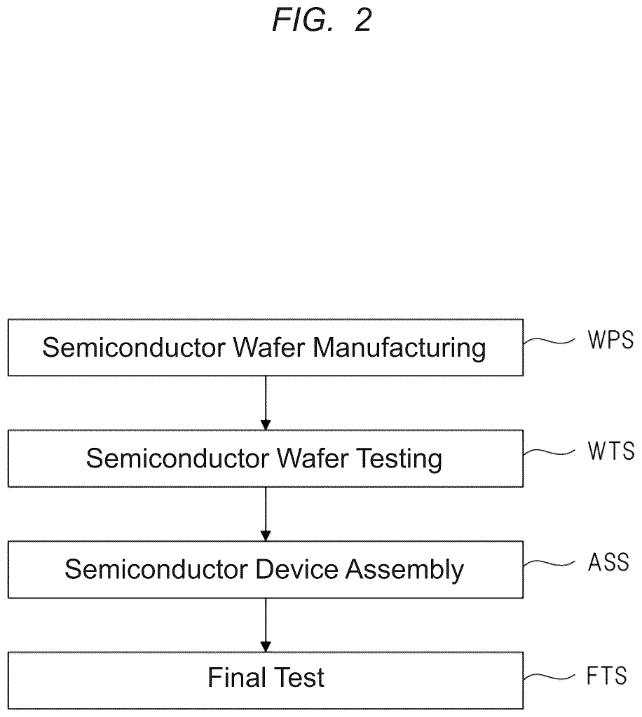

Next, the manufacturing method of the semiconductor device CHP according to the first embodiment shown in FIG. 1 will be described with reference to the drawings. FIG. 2 is a flowchart showing the manufacturing method of the semiconductor device according to the first embodiment.

As described in FIG. 1, the semiconductor device CHP includes a semiconductor chip. In the semiconductor device manufacturing method, first, a semiconductor wafer with a plurality of semiconductor chips is prepared. In FIG. 2, WPS represents the semiconductor wafer manufacturing process for producing a semiconductor wafer with a plurality of semiconductor chips, and WTS represents the semiconductor wafer testing process for testing the semiconductor wafer.

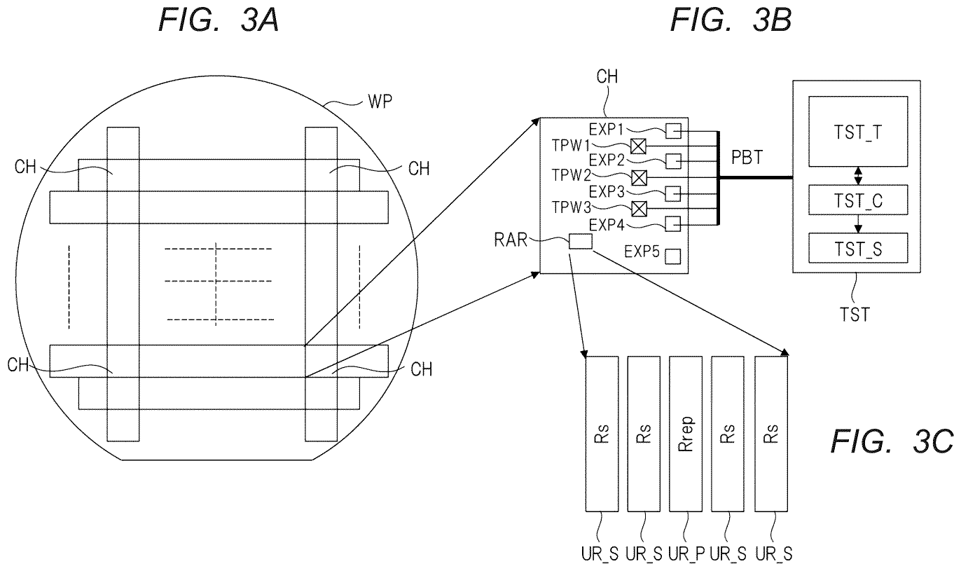

Examples of semiconductor wafers manufactured in the semiconductor wafer manufacturing process WPS, tests conducted in the semiconductor wafer testing process WTS, and examples of semiconductor chips are described with reference to the drawings. FIG. 3 is a diagram for explaining the semiconductor wafer, semiconductor wafer testing process, and semiconductor chip according to the first embodiment. Here, FIG. 3A is a plan view of the semiconductor wafer seen from above, FIG. 3B is a conceptual diagram showing the connection between the semiconductor chip arranged on the semiconductor wafer and the tester device, and FIG. 3C is a plan view showing examples of sense resistors and replica resistors arranged on the semiconductor chip.

In FIG. 3A, WP indicates the semiconductor wafer, and CH arranged on the semiconductor wafer WP indicates the semiconductor chips. In the semiconductor wafer manufacturing process WPS, active elements, passive elements, and pads are formed within the area of each semiconductor chip CH arranged on the semiconductor wafer WP using well-known semiconductor manufacturing techniques, and these are electrically connected by wiring layers. This allows various circuit blocks (for example, the drive circuit HLD, memory circuit MEM, control driver DRV, and control circuit CNT shown in FIG. 1) to be realized on each semiconductor chip CH.

The semiconductor wafer WP manufactured in the semiconductor wafer manufacturing process is then tested by a tester device in the semiconductor wafer testing process WTS. In the semiconductor device manufacturing method according to the first embodiment, data setting (writing) is performed on the semiconductor chip CH by the tester device according to the test results in the semiconductor wafer testing process WTS.

An example of a tester device used in the semiconductor wafer testing process WTS is indicated by the code TST in FIG. 3B. The tester device TST is not particularly limited but includes a control unit TST_C, a test unit TST_T controlled by the control unit TST_C, and a setting unit TST_S also controlled by the control unit TST_C.

The test unit TST_T includes a test power circuit, a test current circuit, and a test measurement circuit for measuring voltage, current, etc. The control unit TST_C controls the test unit TST_T, the setting unit TST_S, and the entire tester device TST, and performs operations such as computation. The setting unit TST_S supplies data to the semiconductor chip CH and performs writing processing.

In FIG. 3B, PBT indicates a probe that electrically contacts the pads arranged on the semiconductor chip CH with the tester device TST. FIG. 3B shows an example where one semiconductor chip CH is connected to the tester device TST by the probe PBT, but in practice, a plurality of semiconductor chips CH arranged on the semiconductor wafer WP are substantially connected to the common tester device TST by the probe PBT, and tests are conducted simultaneously.

In FIG. 3B, the pads indicated by the codes TPW1 to TPW3 represent the pads shown in FIG. 1 (for example, TPW1_1, TPW2_1, TPW3_1), and the codes EXP1 to EXP5 indicate the pads connected to external terminals (for example, output external terminal OUT) in the semiconductor device assembly process ASS (FIG. 2) shown in FIG. 1.

Also, in FIG. 3B, the area indicated by the code RAR shows an example of the resistance area where the sense resistor Rs and replica resistor Rrep shown in FIG. 1 are arranged. The resistance area RAR is not particularly limited, but five identical unit resistors are arranged adjacent to each other. Here, the sense resistor Rs is configured by four-unit resistors UR_S among the five-unit resistors, and the replica resistor Rrep is configured by one unit resistor UR_P arranged to be sandwiched between the four-unit resistors UR_S.

The semiconductor wafer testing process WTS will be further explained later with reference to the drawings, so no further explanation is provided here. Returning to FIG. 2, the explanation of the semiconductor device manufacturing method continues.

The semiconductor wafer WP tested in the semiconductor wafer testing process WTS proceeds to the semiconductor device assembly process ASS. In this semiconductor device assembly process ASS, a plurality of semiconductor chips CH are cut out from the semiconductor wafer WP by dicing. In this assembly process ASS, among the pads arranged on the cut-out semiconductor chips, the pads connected to external terminals (codes EXP1 to EXP5 in FIG. 3B) are electrically connected to external terminals (such as code OUT in FIG. 1), and the semiconductor chips are further sealed with resin or the like. This completes the semiconductor device CHP.

Subsequently, the completed semiconductor device CHP is tested in the final test process FTS, and semiconductor devices CHP determined to be good products are shipped.

### <Correction in the Semiconductor Wafer Testing Process>

In the semiconductor device manufacturing method according to the first embodiment, resistance variations caused by manufacturing fluctuations are determined in the semiconductor wafer testing process, and the reference current supplied to the reference resistor Rref is corrected to a value that reduces resistance variations. More specifically, the semiconductor wafer testing process WTS includes the first test process WTS1, the second test process WTS2, and the third test process (also referred to as the setting process) WTS3, and in the first test process WTS1, resistance variations are determined, and in the third test process WTS3, data that reduces resistance variations is set in the current circuit.

### <<Current Flowing Through Power Devices, Sense Resistor, Reference Resistor, and Reference Current>>

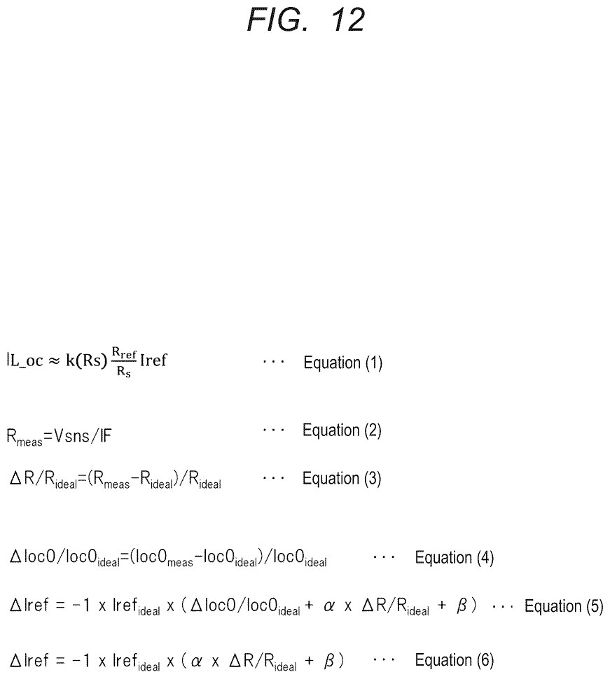

Before explaining the first test process WTS1 to the third test process WTS3 in detail, the relationship between the current IL_oc detected by the overcurrent detection circuit OIDT_H (FIG. 1), the sense resistor Rs, the reference resistor Rref, and the reference current Iref shown in FIG. 1 are described. FIG. 12 is a diagram for explaining the first embodiment.

The overcurrent detection circuit OIDT_H detects a current proportional to the current IL flowing through the source-drain path of the N-type transistor PWT, but the current IL_oc detected by the overcurrent detection circuit OIDT_H is equivalently represented by the equation (1) shown in FIG. 12.

In equation (1), K(Rs) indicates the size ratio K mentioned earlier, but the size ratio depends on the resistance value of the sense resistor Rs and is proportional to the sense resistor Rs. Therefore, in equation (1), the size ratio is expressed as a variable (Rs) of the sense resistor Rs. As understood from equation (1), if the resistance value of the sense resistor Rs varies, the size ratio K will also vary, resulting in variations in the detected current IL_oc, causing detection errors and reducing accuracy. Since the variation in the size ratio K is proportional to the variation in the sense resistor Rs, it is possible to reduce the change in the current IL_oc due to manufacturing fluctuations by changing (correcting) the reference current Iref in the direction opposite to the variation (opposite direction to the variation). In other words, by appropriately correcting the reference current Iref, it is possible to reduce the decrease in accuracy due to resistance variations caused by manufacturing fluctuations.

In equation (1), if the sense resistor Rs on the right side is moved to the left side and rewritten, it can be seen that the comparison circuit CMP shown in FIG. 1 compares the voltage (IL_oc×Rs) on the left side of equation (1) with the voltage ((K(Rs)×Rref×Iref) on the right side. In this case, the value of the current IL_oc in equation (1) represents the threshold of the overcurrent detection circuit OIDT_H when the overcurrent detection signal OID_H changes from low level to high level.

### <<First Test Process, Second Test Process, and Third Test Process (Setting Process)>>

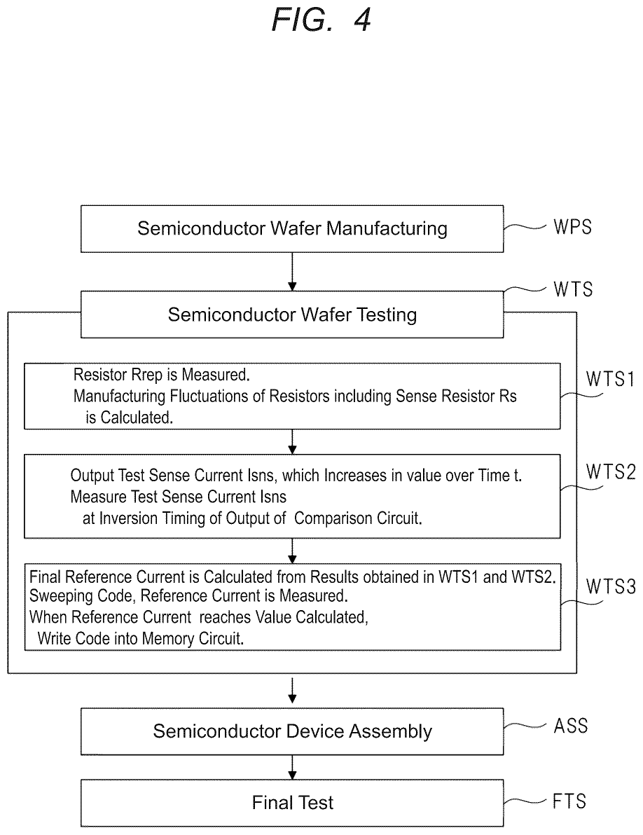

Next, the first test process WTS1, the second test process WTS2, and the third test process WTS3 according to the first embodiment are described with reference to the drawings. FIG. 4 is a flowchart showing the semiconductor wafer testing process according to the first embodiment in detail. FIG. 4 is similar to FIG. 2. The main difference is that FIG. 4 shows the first test process, second test process, and third test process executed in the semiconductor wafer testing process WTS in detail.

### <<<First Test Process WTS1>>>

In the first test process WTS1, the resistance value of the replica resistor Rrep is measured by the tester device TST, and the resistance value variation (fluctuation) due to manufacturing fluctuations of the resistors including the sense resistor Rs is calculated (estimated) by the tester device TST from the measured resistance value of the replica resistor Rrep.

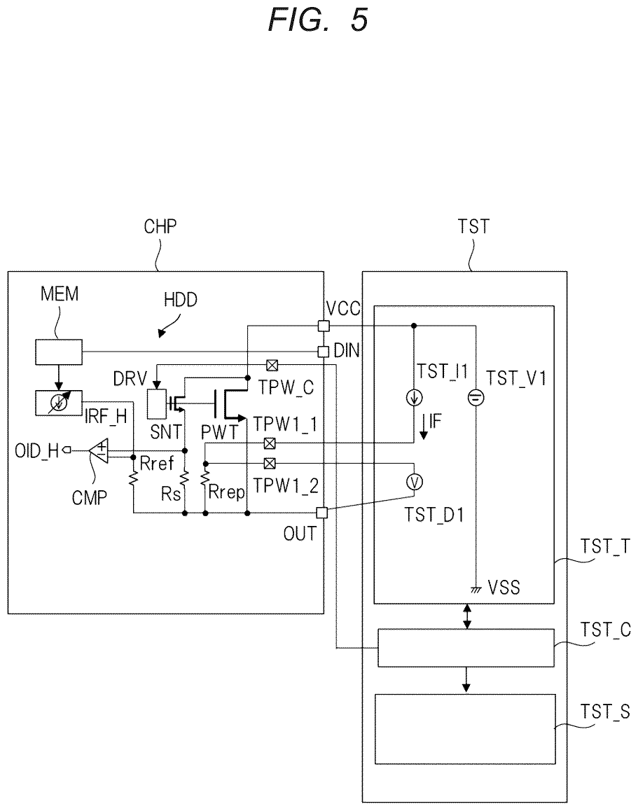

The state of the semiconductor device CHP and the tester device TST during the first test process WTS1 will be described with reference to the drawings. FIG. 5 is a diagram for explaining the first test process according to the first embodiment. FIG. 5 is a drawing that combines FIG. 1 and FIG. 3B. That is, FIG. 5 shows the high-side drive circuit HDD, the memory circuit MEM, and the control driver DRV as the semiconductor device CHP shown in FIG. 1. Since the drawing becomes complicated, the control driver DRV is depicted in a simplified manner compared to FIG. 1. Furthermore, only the pads and external terminals necessary for explanation are depicted in FIG. 5. Also, FIG. 5 shows only the tester device TST (control unit TST_C, test unit TST_T, and setting unit TST_S) as shown in FIG. 3B.

In the first test process WTS1, the control unit TST_C supplies the power voltage from the test power supply circuit TST_V1 in the test unit TST_T to the power terminal VCC of the semiconductor device CHP. Also, in the first test process WTS1, the control unit TST_C supplies the test current IF from the test current circuit TST_I1 in the test unit TST_T to the pad TPW1_1 in the semiconductor device CHP and measures the voltage between the pad TPW1_2 and the output terminal OUT in the semiconductor device CHP using the test measurement circuit TST_D1. Furthermore, during the first test process WTS1, the control unit TST_C supplies a control signal to the control driver DRV via the pad TPW_C to control the control driver DRV so that the N-type transistors PWT and SNT are in a non-conductive state.

As shown in FIG. 5, one end of the replica resistor Rrep is connected to the pads TPW1_1 and TPW1_2, and the other end of the replica resistor Rrep is connected to the output terminal OUT.

If the voltage measured by the test measurement circuit TST_D1, that is, the voltage drop value at the replica resistor Rrep generated by the test current IF, is Vsns, the control unit TST_C performs the calculation of equation (2) shown in FIG. 12 based on the test current IF from the test current circuit TST_I1 and the voltage Vsns measured by the test measurement circuit TST_D1, and calculates the resistance value Rmeas of the replica resistor Rrep in the semiconductor device CHP.

Next, the control unit TST_C determines the difference ΔR between the calculated resistance value Rmeas of the replica resistor Rrep and the ideal value Rideal of the replica resistor Rrep. This difference ΔR becomes the variation in resistance including the sense resistor Rs caused by manufacturing variations. In the first embodiment, the difference ΔR is normalized based on the ideal value Rideal. That is, the control unit TST_C executes equation (3) shown in FIG. 12 to calculate the normalized difference ΔR/Rideal. This difference ΔR/Rideal is also referred to as the resistance variation rate in this specification. The ideal value Rideal of the replica resistor Rrep is, for example, the resistance value at the time of design.

### <<<Second Test Process WTS2>>>

After calculating the resistance variation rate due to manufacturing variations, the second test process is executed. In the second test process, the variation of other parts (e.g., comparison circuit CMP) excluding the variation of the sense resistor Rs caused by manufacturing variations is determined.

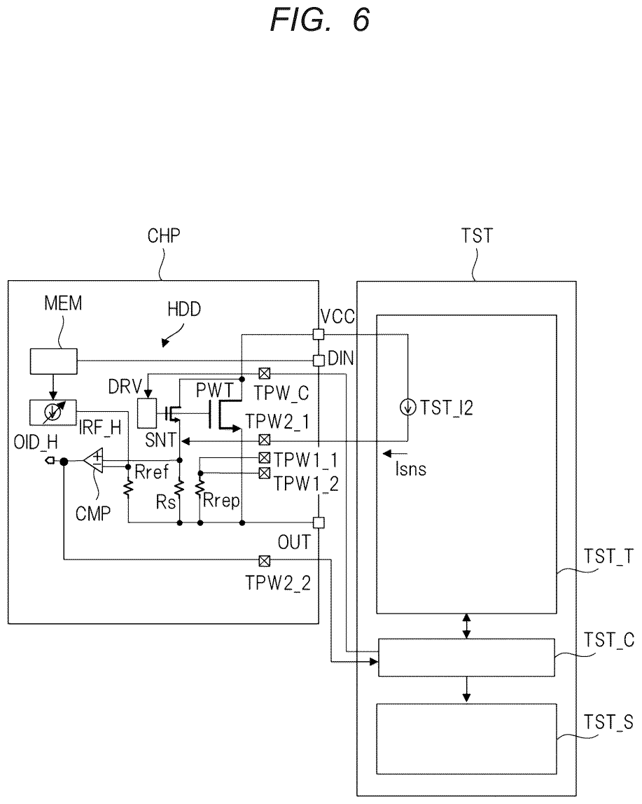

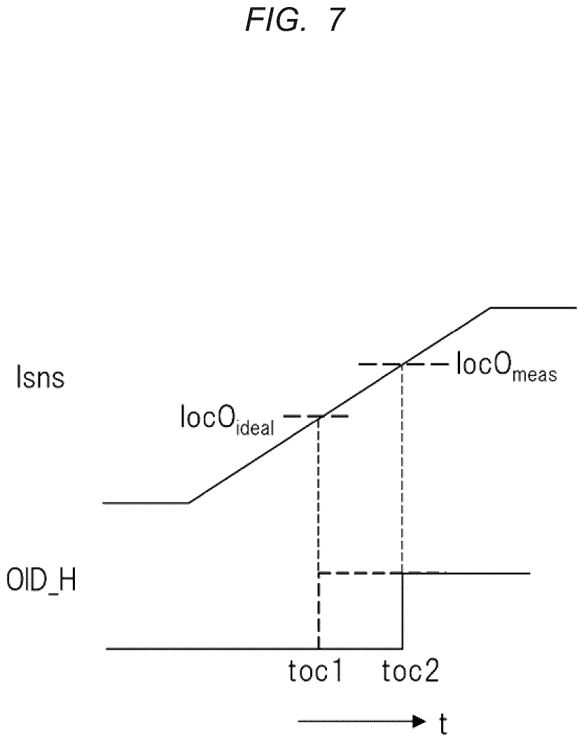

The state of the semiconductor device CHP and the tester device TST during the second test process WTS2 will be described with reference to the drawings. FIG. 6 and FIG. 7 are diagrams for explaining the second test process according to the first embodiment. FIG. 6 is similar to FIG. 5. The difference is that in the semiconductor device CHP in FIG. 6, the pads TPW2_1 and TPW2_2 are explicitly shown, and the state of the tester device TST is in the state of the second test process WTS2.

The pad TPW2_1 is connected to a connection node that connects the source of the N-type transistor SNT and the sense resistor Rs. Also, the pad TPW2_2 is connected to the output terminal of the comparison circuit CMP.

In the tester device TST, during the second test process WTS2, the control unit TST_C connects the test current circuit TST_I2 in the test unit TST_T between the power terminal VCC of the semiconductor device CHP and the pad TPW2_1 and supplies the test sense current Isns from the test current circuit TST_I2 to the connection node. Also, as in the first test process WTS1, the control unit TST_C controls the control driver DRV in the second test process WTS2 to make the N-type transistors PWT and SNT non-conductive.

Furthermore, in the second test process WTS2, the control unit TST_C monitors the overcurrent detection signal OID_H, which is the output of the comparison circuit CMP supplied to the pad TPW2_2 and detects the timing (inversion timing) when the logic value (level) of the overcurrent detection signal OID_H is inverted. The control unit TST_C measures the current value of the test sense current Isns at the inversion timing.

FIG. 7 shows the relationship between the test sense current Isns output from the test current circuit TST_I2 and the overcurrent detection signal OID_H. The test current circuit TST_I2 according to the first embodiment forms and outputs the test sense current Isns, which increases in value over time t, as shown in FIG. 7, during the second test process WTS2. The control unit TST_C measures the test sense current Isns at the inversion timing (the timing when it inverts from low level to high level) of the overcurrent detection signal OID_H.

In FIG. 7, the time toc2 indicates the timing when the level of the overcurrent detection signal OID_H is inverted while the test sense current Isns is applied to the connection node between the source of the N-type transistor SNT and the sense resistor Rs during the second test process WTS2. At this time, the value of the test sense current Isns measured by the control unit TST_C is indicated by the symbol Ioc0meas. In contrast, the time toc1 and the symbol Ioc0ideal shown in FIG. 7 indicate the ideal inversion timing and the ideal value of the test sense current Isns.

The control unit TST_C determines the difference ΔIoc0 between the measured test current value Ioc0meas and the ideal test current value Ioc0ideal. This difference ΔIoc0 becomes the variation excluding the sense resistor Rs due to manufacturing variations. In the first embodiment, the variation, which is the difference ΔIoc0, is also normalized based on the ideal value Ioc0ideal, similar to the variation, which is the difference ΔR. That is, the control unit TST_C executes equation (4) shown in FIG. 12 to calculate the normalized difference ΔIoc0/Ioc0ideal. This difference ΔIoc0/Ioc0ideal is also referred to as the current variation rate in this specification. The ideal inversion timing toc1 and the ideal test current value Ioc0ideal are, for example, the inversion timing and test current value at the time of design.

### <<<Third Test Process WTS3>>>

In the third test process WTS3, the final reference current is calculated from the results obtained in the first test process WTS1 and the second test process WTS2, and the current value supplied to the reference resistor Rref is set to the calculated reference current, and the current circuit is set accordingly.

The control unit TST_C calculates the resistance variation rate for the sense resistor Rs by multiplying the resistance variation rate ΔR/Rideal calculated in equation (3) shown in FIG. 12 by a constant α and adding a constant β. Here, the constants α and β are constants determined from the variation in resistance and the variation in size ratio K, which were previously calculated by simulation. The control unit TST_C calculates the variation value caused by manufacturing discrepancies by adding the current variation rate (ΔIoc0/Ioc0ideal) calculated in the second test process WTS2 to the resistance variation rate concerning the sense resistor Rs (α×ΔR/Rideal+β) as shown in equation (5) in FIG. 12 and further multiplying by the ideal reference current value Irefideal. To reduce or offset the calculated variation value through correction, the calculated variation value is multiplied by −1 to determine the variation value ΔIref that needs to be corrected. This variation value ΔIref is added to the reference current Iref that should be generated by the variable current circuit IRF_H and is set in the variable current circuit IRF_H.

As a configuration to set in the variable current circuit IRF_H, the control unit TST_C executes equation (5) to determine the variation value ΔIref, calculates the reference current Iref by adding this variation value ΔIref, and may set it in the memory circuit MEM. In this case, the H current data IRD_H (FIG. 1) according to the value set in the memory circuit MEM is output from the memory circuit MEM to the variable current circuit IRF_H.

However, to ensure that a more accurate reference current is output from the variable current circuit IRF_H, in the first embodiment, the following process is performed in the third test process WTS3.

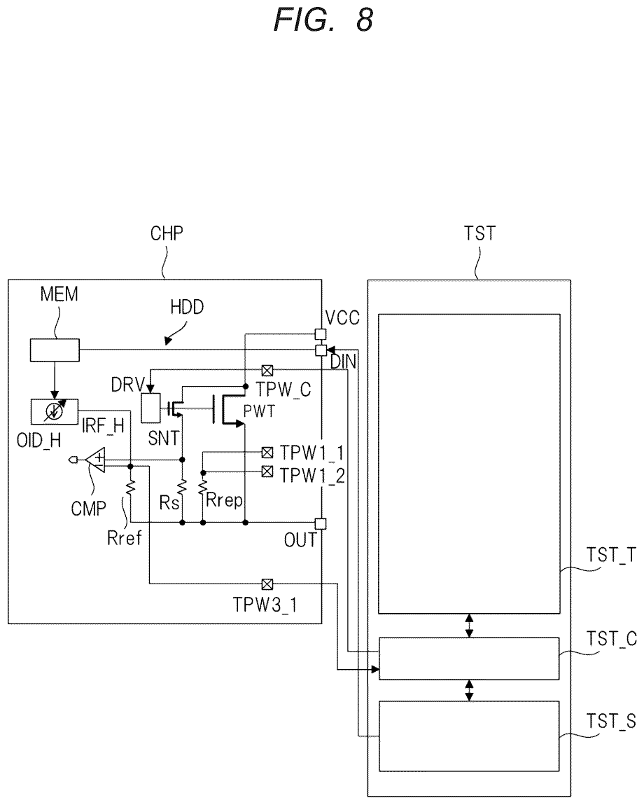

FIG. 8 is a diagram for explaining the third test process according to the first embodiment. FIG. 8 is similar to FIG. 5. The difference is that in the semiconductor device CHP in FIG. 8, the pad TPW3_1 is explicitly shown, and the state of the tester device TST is in the state of the third test process WTS3.

The pad TPW3_1 is connected to the connection node that connects the reference resistor Rref and the variable current circuit IRF_H.

In the tester device TST, as in the second test process WTS2, the control unit TST_C controls the control driver DRV to make the N-type transistors PWT and SNT non-conductive. Also, the setting unit TST_S within the tester device TST is connected to the memory circuit MEM via the input terminal DIN.

In the third test process WTS3, the control unit TST_C instructs the setting unit TST_S to sequentially change (sweep the code) the H current data IRD_H (FIG. 1) supplied to the variable current circuit IRF_H via the memory circuit MEM. As a result, the variable current circuit IRF_H sequentially outputs the reference current value according to the supplied H current data IRD_H. The control unit TST_C measures (grasps) the value of the currently output reference current from the value supplied via the pad TPW3_1. When the measured current value of the reference current Iref reaches the value obtained by adding the variation value ΔIref calculated based on equation (5), the control unit TST_C instructs the memory circuit MEM via the setting unit TST_S to write the H current data IRD_H into the memory circuit MEM. This allows for setting while grasping the actual reference current Iref value, enabling the setting of a more accurate reference current.

The memory circuit MEM is equipped with a fuse, for example, and upon instruction from the setting unit TST_S, the H current data IRD_H is written into the fuse. In the semiconductor device CHP after shipment, the reference current corresponding to the H current data IRD_H written into the fuse is output from the variable current circuit IRF_H, thereby improving accuracy.

Thus, the third test process WTS3 can be regarded as comprising a current measurement process that measures the reference current output from the variable current circuit IRF_H while sequentially changing the H current data, and a writing process that writes the H current data into the memory circuit MEM when the measured current value of the reference current reaches a correction value that reduces or offsets the fluctuation value.

### <<<Configuration of Variable Current Circuit>>>

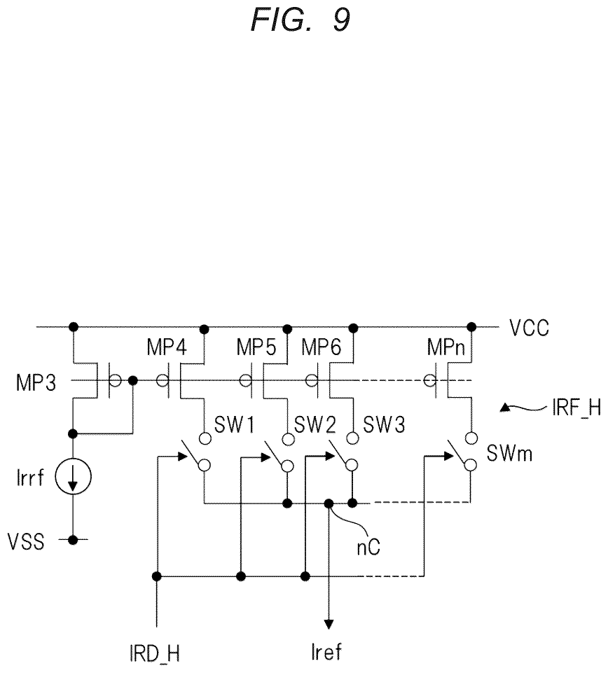

FIG. 9 is a circuit diagram showing the configuration of the variable current circuit according to the first embodiment. As shown in FIG. 9, the variable current circuit IRF_H shown in FIG. 1, etc., includes P-type transistors MP3 to MPn, a current source Irrf, and switches SW1 to SWm controlled by the H current data IRD_H from the memory circuit MEM. The P-type transistor MP3 and the current source Irrf are connected in series between the power supply voltage VCC and the ground voltage VSS, and the gates of the P-type transistors MP3 to MPn are commonly connected to the connection node between the P-type transistor MP3 and the current source Irrf. Furthermore, as shown in FIG. 9, the P-type transistors MP4 to MPn and the switches SW1 to SWm are connected in series between the power supply voltage VCC and the common node nC. This common node nC is connected to the negative input terminal (−) of the comparison circuit CMP shown in FIG. 1, for example, and outputs the reference current Iref.

Among the switches SW1 to SWm, the number of switches corresponding to the H current data IRD_H from the memory circuit MEM becomes conductive, and the reference current Iref corresponding to the value of the H current data IRD_H is supplied to the reference resistor Rref.

FIG. 4 shows an example of implementing both the first test process WTS1 and the second test process WTS2, but it is not limited to this. For example, the second test process WTS2 may not be implemented, and the first test process WTS1 and the third test process WTS3 may be implemented. In this case, in the third test process WTS3, the fluctuation value ΔIref of the reference current can be calculated by executing equation (6) instead of equation (5) shown in FIG. 12.

In the first embodiment, the resistance fluctuation rate and the current fluctuation rate caused by manufacturing variations are calculated in the semiconductor wafer test process WTS, rather than in the final test process FTS, thereby improving the accuracy of the overcurrent detection circuit. That is, the accuracy of the overcurrent detection circuit is improved before the final test process FTS, which reduces the waste of materials and labor applied to the semiconductor device and improves the overall yield. Furthermore, in the first embodiment, processing to improve the accuracy of the overcurrent detection circuit is performed in the semiconductor wafer test process WTS, but this processing does not require supplying large currents to the pads or external terminals of the semiconductor chip, allowing simultaneous processing of a plurality of semiconductor chips arranged on the semiconductor wafer, thereby shortening the processing time.

### Second Embodiment

In the first embodiment, an example of improving the accuracy of the overcurrent detection circuit during the manufacturing process of the semiconductor device was explained. In the second embodiment, an example of a semiconductor device capable of improving the accuracy of the overcurrent detection circuit will be explained.

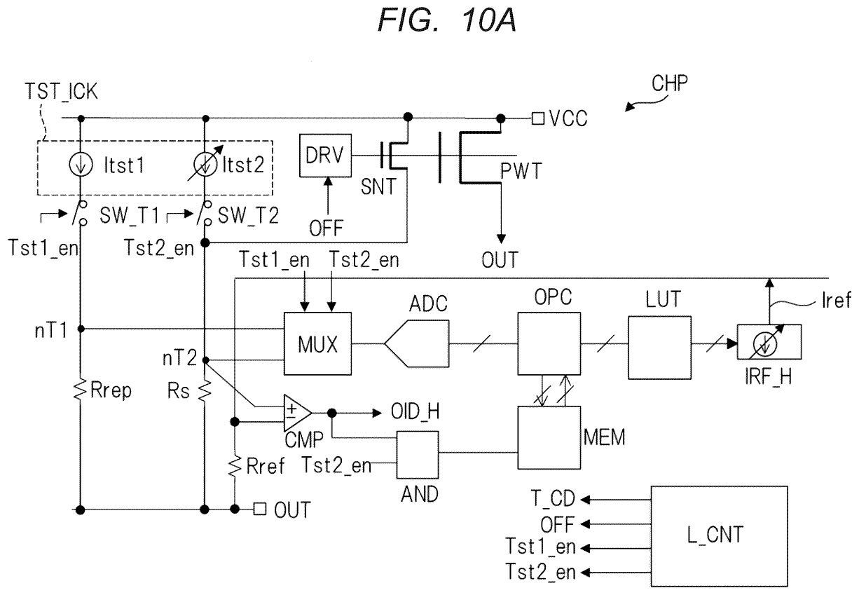

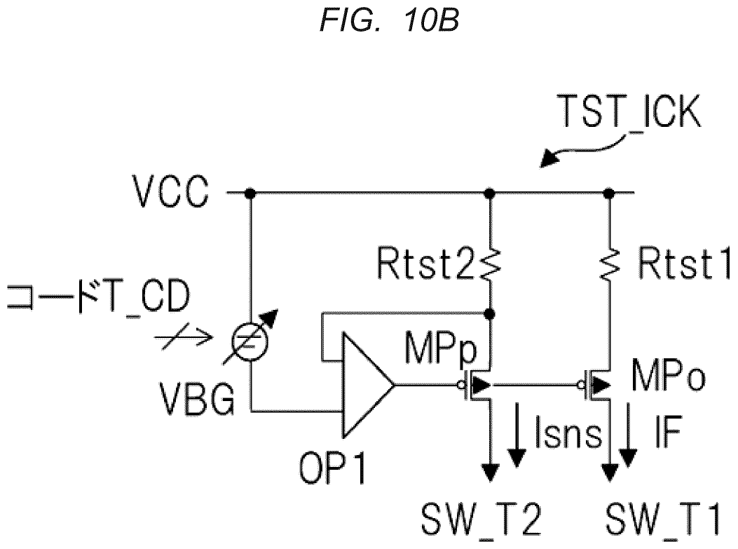

FIG. 10 is a diagram showing the configuration of a semiconductor device according to the second embodiment. Here, FIG. 10A is a block diagram showing the main part of the semiconductor device, and FIG. 10B is a circuit diagram showing the configuration of the test current circuit.

To avoid complexity in the drawings, only the high-side drive circuit HDD (FIG. 1) of the semiconductor device CHP is depicted in FIG. 10A.

In FIG. 10A, PWT indicates a power transistor (N-type transistor) as a power device, and SNT indicates a sense transistor (N-type transistor) as a sense device. The source-drain path of the power transistor PWT is connected between the power supply terminal VCC and the output terminal OUT, and the source-drain path of the sense transistor SNT is connected between the power supply terminal VCC and the connection node nT2, with a sense resistor Rs connected between the connection node nT2 and the output terminal OUT. The gates of the sense transistor SNT and the power transistor PWT are connected to the control driver DRV, and when overcurrent is not detected, the sense transistor SNT and the power transistor PWT are driven by the drive signal from the control driver DRV.

In FIG. 10A, Rrep indicates a replica resistor, which is arranged adjacent to the sense resistor Rs, similar to the first embodiment. Also, in FIG. 10A, TST_ICK indicates the test current circuit. The test current circuit TST_ICK, which will be exemplified later using FIG. 10B, includes a fixed current circuit Itst1 and a variable current circuit Itst2. The fixed current circuit Itst1, switch SW_T1, and replica resistor Rrep are connected in series between the power supply terminal VCC and the output terminal OUT, and the variable current circuit Itst2 and switch SW_T2 are connected in series between the power supply terminal VCC and the connection node nT2. Switch SW_T1 becomes conductive when the first test signal Tst1_en is at a high level (selection level), and switch SW_T2 becomes conductive when the second test signal Tst2_en is at a high level (selection level).

Similar to the first embodiment, the comparison circuit CMP, which outputs the overcurrent detection signal OID_H, has its negative input terminal (−) connected to the output terminal OUT via the reference resistor Rref, and the positive input terminal (+) connected to the connection node nT2. Furthermore, the reference current Iref is supplied to the negative input terminal (−) from the variable current circuit IRF_H.

In the semiconductor device CHP according to the second embodiment, a compensation circuit is configured to reduce the fluctuation value caused by manufacturing variations, using the multiplexer MUX, analog/digital conversion circuit (also referred to as AD circuit) ADC, operation circuit OPC, lookup table LUT, AND circuit AND, and memory circuit MEM, as described below.

### <Compensation Circuit>

The multiplexer MUX is connected to the connection node nT1, which connects the switch SW_T1 and the replica resistor Rrep, and to the connection node nT2, and selects the connection node nT1 or nT2 according to the first test signal Tst1_en and the second test signal Tst2_en. For example, when the first test signal Tst1_en is at a high level, the multiplexer MUX selects the connection node nT1, and when the second test signal Tst2_en is at a high level, it selects the connection node nT2. The analog signal at the connection node selected by the multiplexer MUX is converted into a digital signal by the AD circuit ADC and supplied to the operation circuit OPC.

The AND circuit AND supplies the output of the comparison circuit CMP to the memory circuit MEM when the second test signal Tst2_en is at a high level. The memory circuit MEM performs data transmission and reception with the operation circuit OPC.

The lookup table LUT stores multiple fluctuation values ΔIref of reference currents and multiple reference current values (corresponding to the H current data IRD_H in FIG. 1) in advance. Here, the reference current values and fluctuation values ΔIref correspond one-to-one. The lookup table LUT selects the reference current value corresponding to the data (fluctuation value of the reference current) supplied from the operation circuit OPC and supplies it to the variable current circuit IRF_H. This allows the variable current circuit IRF_H to generate the reference current Iref corresponding to the supplied reference current value and supply it to the reference resistor Rref.

In FIG. 10A, L_CNT indicates a control circuit. The control circuit L_CNT controls the control driver DRV with the control signal OFF to make the power transistor PWT and the sense transistor SNT non-conductive before using the semiconductor device CHP. Next, the control circuit L_CNT sets the power transistor PWT and the sense transistor SNT to a non-conductive state, raises the first test signal Tst1_en to a high level, then lowers the first test signal Tst1_en to a low level, and subsequently raises the second test signal Tst2_en to a high level. This operation, aimed at reducing variations caused by manufacturing discrepancies, is performed by the compensation circuit.

Next, an example of the test current circuit TST_ICK will be described with reference to FIG. 10B. The test current circuit TST_ICK includes current limiting resistors Rtst1 and Rtst2, P-type transistors MPo and MPp, an operational amplifier OP1, and a variable voltage circuit VBG that supplies a voltage value according to the code (data) T_CD to the operational amplifier OP1.

The source-drain path of the current limiting resistor Rtst1 and the P-type transistor MPo is connected in series between the power supply voltage VCC and the switch SW_T1, and the gate of the P-type transistor MPo is connected to the output terminal of the operational amplifier OP1. The fixed current circuit Itst1 is configured by the P-type transistor MPo and the current limiting resistor Rtst1 supplied with the output of the operational amplifier OP1, and the test current IF is output.

The source-drain path of the current limiting resistor Rtst2 and the P-type transistor MPp is connected in series between the power supply voltage VCC and the switch SW_T2, and the gate of the P-type transistor MPp is connected to the output terminal of the operational amplifier OP1. Additionally, one input of the operational amplifier OP1 is connected to the connection node between the P-type transistor MPp and the current limiting resistor Rtst2. The output voltage of the variable voltage circuit VBG is supplied to the other input of the operational amplifier OP1. Since the output voltage of the variable voltage circuit VBG changes according to the code T_CD, the value of the test sense current Isns supplied to the switch SW_T2 changes according to the code T_CD due to the feedback operation of the operational amplifier OP1. In other words, the variable current circuit Itst2 is configured by the current limiting resistor Rtst2, the P-type transistor MPp, and the operational amplifier OP1. It should be noted that the code T_CD, which is not particularly limited, is output from the control circuit L_CNT and changes (increases or decreases) over time.

### Operation Example

When the first test signal Tst1_en becomes high level, the test current IF is supplied from the fixed current circuit Itst1 to the replica resistor Rrep. The multiplexer MUX selects the connection node nT1, and the voltage at the connection node nT1 is converted by the AD circuit ADC and supplied to the arithmetic circuit OPC. Since the value of the test current IF is known in advance, the arithmetic circuit OPC performs the calculation shown in equation (2) of FIG. 12 using the value of the test current IF and the voltage value from the AD circuit ADC. Furthermore, the arithmetic circuit OPC uses the ideal value of the replica resistor Rrep and the calculation result of equation (2) to perform the calculation of equation (3) of FIG. 12 and calculates the resistance variation rate ΔR/Rideal.

Next, the second test signal Tst2_en becomes high level. At this time, the control circuit L_CNT supplies the code T_CD, which changes over time, to the test current circuit TST_ICK. As a result, the test current circuit TST_ICK outputs the test sense current Isns that changes over time, as shown in FIG. 7. This test sense current Isns is supplied to the connection node nT2 and then to the sense resistor Rs.

The AND circuit supplies the output of the comparison circuit CMP to the memory circuit MEM when the second test signal Tst2_en is high level. Therefore, the comparison results between the sense voltage generated by the test sense current Isns at the sense resistor Rs and the reference voltage generated by the reference resistor Rref is supplied to the memory circuit MEM. Additionally, the sense voltage generated by the test sense current Isns at the sense resistor Rs is further converted by the AD circuit ADC via the multiplexer MUX and supplied to the arithmetic circuit OPC.

The arithmetic circuit OPC selects the voltage supplied from the AD circuit ADC at the timing when the comparison result of the comparison circuit CMP stored in the memory circuit MEM indicates inversion. The arithmetic circuit OPC calculates the current Ioc0meas shown in equation (4) of FIG. 12 by dividing the selected voltage by the sense resistor Rs and performs the calculation of equation (4) using the calculated value and the ideal value Ioc0ideal to calculate the current variation rate ΔIoc0/Ioc0ideal.

Subsequently, the arithmetic circuit OPC uses the calculated resistance variation rate ΔR/Rideal and the current variation rate ΔIoc0/Ioc0ideal to perform the calculation of equation (5) of FIG. 12, thereby calculating the variation value ΔIref of the reference current and supplying it to the lookup table LUT. Based on this variation value ΔIref, the lookup table LUT selects the corresponding reference current value from the stored multiple reference current values and supplies the selected reference current value to the variable current circuit IRF_H. An example of the variable current circuit IRF_H is described in FIG. 9, so it is omitted here.

In the second embodiment, as in the first embodiment, the replica resistor Rrep is configured by unit resistors, and the sense resistor Rs is configured by combining a plurality of identical unit resistors. Of course, when viewed in plain view, the unit resistors constituting the replica resistor are arranged adjacent to the unit resistors constituting the sense resistor Rs.

In FIG. 10, an example of calculating the variation value ΔIref using the resistance variation rate ΔR/Rideal and the current variation rate ΔIoc0/Ioc0ideal was described, but as in the first embodiment, it is also possible to calculate the variation value ΔIref using only the resistance variation rate ΔR/Rideal (equation (6) of FIG. 12).

In the first and second embodiments, the symbol DRV was referred to as the control driver to distinguish it from the drive circuit HLD (for example, FIG. 1), but the symbol DRV can also be considered a drive circuit because it outputs the drive signals DRV_H and DRV_L.

### Additional Statement

This specification discloses a plurality of inventions, some of which are described in the claims, but other inventions are also disclosed, and the representative ones are listed below. (A) A semiconductor device comprising a power transistor, a gate connected to the gate of the power transistor, a sense transistor with a source connected to a predetermined node via a sense resistor, a reference resistor connected between the current circuit and the predetermined node, a comparison circuit that compares the sense voltage generated by the sense current supplied from the sense transistor to the sense resistor with the reference voltage generated by the reference current supplied from the current circuit to the reference resistor to form an overcurrent detection signal, a drive circuit that supplies a drive signal to the gate of the power transistor when overcurrent is not detected by the overcurrent detection signal, a replica resistor arranged adjacent to the sense resistor, a test current circuit that supplies a first test current to the replica resistor, and a compensation circuit that determines the resistance variation rate of the replica resistor caused by manufacturing variations based on the replica voltage generated by the first test current, determines the variation value of the reference current based on the resistance variation rate, and sets the current value of the current circuit to reduce the variation value. (B) In the semiconductor device described in Additional Statement (A), the test current circuit supplies a second test current that changes over time to the sense resistor, and the compensation circuit determines the current variation rate, which is the difference between the value of the second test current when the output of the comparison circuit is inverted and the ideal value of the second test current that inverts the output of the comparison circuit, determines the variation value of the reference current based on the resistance variation rate and the current variation rate, and generates the reference current with a value that reduces the variation value using the current circuit. (C) In the semiconductor device described in Additional Statement (B), the sense resistor is formed by a combination of a plurality of unit resistors, and the replica resistor is formed by the unit resistors.

Although the invention made by the present inventor has been specifically described based on the embodiment, the present invention is not limited to the embodiment described above, and it is needless to say that various modifications can be made without departing from the gist thereof.

What is claimed is:

1. A manufacturing method of a semiconductor device, the method comprising:
a semiconductor wafer manufacturing process in which a plurality of semiconductor chips, each having a power device and an overcurrent detection circuit that detects a current flowing through the power device, are arranged;
a semiconductor wafer testing process for testing the semiconductor wafer; and
a semiconductor device assembly process having dicing the plurality of semiconductor chips from the semiconductor wafer and assembling a semiconductor device equipped with the diced semiconductor chip,
wherein the overcurrent detection circuit includes:
a sense device through which a sense current proportional to the current flowing through the power device flows,
a sense resistor connected between the sense device and a predetermined node,
a reference resistor connected between the predetermined node and a current circuit, and
a comparison circuit that compares the sense voltage generated in the sense resistor by the sense current with the reference voltage generated in the reference resistor by the reference current from the current circuit to form an overcurrent detection signal,
wherein the semiconductor chip includes a replica resistor arranged adjacent to the sense resistor,
wherein the semiconductor wafer testing process includes:
a first testing process to determine the resistance variation rate of the replica resistor due to manufacturing variations when manufacturing the semiconductor wafer, and
a setting process to determine the variation value of the reference current based on the resistance variation rate determined in the first testing process and set the current value of the current circuit to reduce the variation value.

2. The manufacturing method of the semiconductor device according to claim 1,
wherein the current circuit includes a variable current circuit that outputs a current value according to supplied data as the reference current, and a storage circuit that stores the data, and
wherein the setting process includes:
a current measurement process that measures the reference current output from the variable current circuit while changing the data supplied to the variable current circuit, and
a writing process that writes the data at the time when the measured current value in the current measurement process reaches a correction value that offsets the variation value into the storage circuit.

3. The manufacturing method of the semiconductor device according to claim 1,
wherein the semiconductor wafer testing process further includes a second testing process that applies a test current to the sense resistor, determines the test current value when the overcurrent detection signal is inverted, and determines the current variation rate between the determined test current value and the ideal test current value, and
wherein, in the setting process, the variation value of the reference current is determined based on the resistance variation rate and the current variation rate, and the current value of the current circuit is set to reduce the variation value.

4. The manufacturing method of the semiconductor device according to claim 3,
wherein the current circuit includes a variable current circuit that outputs a current value according to supplied data as the current reference, and a storage circuit that stores the data, and
wherein the setting process includes:
a current measurement process that measures the reference current output from the variable current circuit while changing the data supplied to the variable current circuit, and
a writing process that writes the data at the time when the measured current value in the current measurement process reaches a correction value that offsets the variation value into the storage circuit.

5. The manufacturing method of the semiconductor device according to claim 4,
wherein the sense device includes a sense transistor with a source connected to the predetermined node via the sense resistor,
wherein the power device includes a gate connected to the gate of the sense transistor and a power transistor larger in size than the sense transistor, and
wherein the power transistor and the sense transistor are in a non-conductive state during the first testing process, the second testing process, and the setting process.

6. The manufacturing method of the semiconductor device according to claim 5,
wherein the resistance variation rate is a normalized value of the difference between the ideal resistance value of the replica resistor and the resistance value of the replica resistor measured in the first testing process, using the ideal resistance value as a unit. The current variation rate is a normalized value of the difference between the test current value determined in the second testing process and the ideal test current value, using the ideal test current value as a unit, which is a method for manufacturing a semiconductor device.

7. The manufacturing method of the semiconductor device according to claim 6,
wherein the sense resistor is formed by a combination of a plurality of unit resistors, and the replica resistor is formed by the unit resistors.

8. A semiconductor device comprising:
a power transistor;
a sense transistor having a gate connected to a gate of the power transistor and a source connected to a predetermined node via a sense resistor;
a reference resistor connected between a current circuit and the predetermined node;
a comparison circuit that compares the sense voltage generated in the sense resistor by the sense current supplied from the sense transistor with the reference voltage generated in the reference resistor by the reference current supplied from the current circuit to form an overcurrent detection signal;
a drive circuit that supplies a drive signal to the gate of the power transistor when overcurrent is not detected by the overcurrent detection signal; and
a replica resistor arranged adjacent to the sense resistor,
wherein the reference current supplied from the current circuit to the reference resistor is set to reduce the variation value of the reference current based on the resistance variation rate of the replica resistor caused by manufacturing variations.

9. The semiconductor device according to claim 8,
wherein the sense resistor is formed by a combination of a plurality of unit resistors, and the replica resistor is formed by the unit resistors.

10. The semiconductor device according to claim 9,
wherein the current circuit includes a variable current circuit that outputs a current value according to supplied data as the reference current, and a storage circuit that stores the data, which is a semiconductor device.
